(19) United States
(12) Patent Application Publication
(10) Pub. No.: US 2003/0122206 A1
(43) Pub. Date: Jul. 3, 2003

(54) Multi-chip module integrating MEMS mirror array with electronics

(76) Inventors: Amal Bhattarai, West Sacramento, CA (US); Narayanan Rajan, Atlanta, GA (US)

Correspondence Address: LAW OFFICES OF CHARLES GUENZER, P O BOX 60729, PALO ALTO, CA, 94306

(21) Appl. No.: 10/290,743

(22) Filed: Nov. 7, 2002

Related U.S. Application Data
(60) Provisional application No. 60/344,467, filed on Nov. 9, 2001.

(30) Foreign Application Priority Data
Nov. 7, 2002 PCT/US02/35890

(51) Int. Cl. H01L 21/00; H01L 29/82

(52) U.S. Cl. 257/415; 438/50; 257/418; 257/419; 438/53

(57) ABSTRACT

An integrated module including an array of electrostatically actuated mirrors usable as an optical switch. An array of tiltable mirrors is formed as a micro electromechanical system (MEMS) in one carrier substrate. A ceramic multi-chip module (MCM) is formed having multiple layers of wiring and electrodes at one surface forming one side part of the electrostatic capacitive actuators. The MEMS substrate is bonded to the carrier with the carrier electrodes in opposition to the mirrors, which form counter electrodes. Advantageously, a handle layer of the MEMS substrate is not removed and the mirrors released until after the bonding with the MCM. Separate high-voltage integrated circuits (ICs) driving the actuators and low-voltage ICs controlling the high-voltage ICs are bonded on the side of the MCM opposite the MEMS with the MCM providing electrical interconnections.

### RELATED APPLICATIONS

This application claims benefit of provisional application 60/344,467, filed Nov. 9, 2001, and is also related to U.S. patent application Ser. No. ______ concurrently filed on Nov. 7, 2002 and entitled MEMS MICRO MIRRORS DRIVEN BY ELECTRODES FABRICATED ON ANOTHER SUBSTRATE. Both these applications are incorporated herein by reference in their entireties.

### BACKGROUND OF THE INVENTION

1. Field of the Invention

The invention relates generally to optical switches used in communications networks. In particular, it relates to an integrated switch module including an array of micro electromechanical system (MEMS) and the controlling electronics.

2. Background Art

Modern optical communication networks are increasingly based upon optical fiber as the long-distance transmission medium. Silica fiber has usable transmission bands around 1550 nm, 1300 nm, and 980 nm, each of which has advantages in particular applications. An optical network requires a switch at each node of the network to route the optical signals around the network. The original switching nodes in fiber networks converted the optical signal received on an input fiber at each input port of the node to electrical form, switched the electrical signal to the desired output port, and reconverted the electrical signal to optical form for transmission on the output fiber. As the data bandwidths have increased, such electronic switching has been deemed to be too expensive and inflexible for increasingly complex networks.

Many recently implemented fiber networks have relied on wavelength division multiplexing (WDM) in which a single optical fiber carries multiple optical signals with respective narrow predetermined bandwidths in one of the above mentioned transmission bands. Although WDM is effective at vastly increasing the transmission capacity of an optical fiber, it further complicates the electronic switching since each optical signal needs to be separately converted to electrical form, separately switched, and separately reconverted to the desired output wavelength.

To avoid the bottleneck at electronic switches in an optical network, many proposals have been made to perform optical switching with an optical cross connect (OXC), in particular transparent optical switching, in which an optical signal is physically switched in different directions while maintaining its original optical form. For a WDM network, it is of course greatly desired that the separate wavelength components be switchable independently of each other. One type of such a transparent OXC that has received much interest involves a micro electromechanical system (MEMS) including an array of individually tiltable mirrors to steer input beams, which have been wavelength separated at the cross connect, toward different output ports. Three-dimensional arrays of MEMS mirrors are particularly advantageous for a large number N of ports since the size of the 3-D MEMS array scales as 2N while other types of optical switches scale generally as N².

A functional and schematic cross-sectional view of a MEMS mirror element 10 such as that described in the related concurrently filed application is illustrated in FIG. 1. It is understood that many mirror elements 10 may be formed in an array on a single substrate 12. A mirror plate 14 is suspended over a cavity 16 formed in the substrate 12 by a pair of torsion beams 18 extending perpendicularly to the plane of the illustration between the mirror plate 14 and a support structure 20 of the substrate 12. A highly reflective mirror 22 is coated on the top surface of the mirror plate 14. The torsion beams 18 are thin and narrow enough that when sufficient torque is applied about the torsion beam axis, the mirror plate 14 tilts about the axis of the torsion beams 18. Other types of torsion beams are known which are arranged in parallel and bend along their lengths causing an element support on their ends to deflect and rotate. Electrostatic force is supplied by drive signals V₁, V₂ selectively applied to two electrodes 24, 26 formed on the substrate 12 beneath the mirror plate 14 across the cavity 16 and on either side of the torsion beam axis. Assuming that the mirror plate 14 is electrically grounded, any positive or negative voltage applied to either electrode 24, 26 will exert an attractive force between that electrode 24, 26 and the associated side of the mirror plate 14 thereby tending to tilt the mirror 20 in one or the other direction. The degree of tilt increases with the magnitude of the applied voltage.

An optical cross connect incorporating an array of tiltable MEMS mirrors is described by Golub et al. (hereafter Golub) in U.S. patent application, Ser. No. 10/120,869, filed Apr. 11, 2002 and incorporated herein by reference in its entirety, and in International Publication No. WO 02/084372 A2. Diffraction gratings or other wavelength dispersive elements demultiplex the WDM wavelength channels, which may number 80 or even more, into separate physical sub-beams, and free-space optics guide the sub-beams to respective one of the MEMS mirrors. To account for the multiplicity of fibers being interconnected and for the desire for two reflections through a fold mirror, a baseline design includes a MEMS chip with an array of 12×80=960 tiltable mirrors spaced at 750 μm in the fiber direction and 470 μm in the wavelength direction. The baseline design can form such an array on a chip having dimensions of about 54 mm×13 mm. While fabrication of such a chip is feasible, it may be desirable for reasons of cost, yield, or simpler technology to divide such an array among several small chips and to join them in a common plane for use with the free optics described by Golub. Such replication, however, requires close alignment between the multiple chips to easily integrate with the single set of Golub's optics. A similar micro mirror array may be used in white-light communication systems although the number of mirrors corresponds generally to the number of fiber so that the number, while significant, is typically much less than in a WDM system.

The tilt of each of the mirrors needs to be closely controlled over a somewhat wide angular range, so the resolution of the tilting voltage applied to the actuators need to be rather fine. Such a drive requirement introduces at least two problems. The 12×80 mirror array mentioned above, assuming four actuators per mirrors requires 3840 actuators, each of which for the most part is separately controlled. Such a large number of actuator signals, particularly for finely resolved signals, creates a significant pin-out problem. For an array of more than 100 mirrors, the standard interconnect technologies of wire bonding and tape automated bonding (TAB) become increasingly more difficult. Attaining 3840 interconnects by conventional means seems infeasible at this time.

Even if wire bonding of so many interconnects were possible, chip area must be used for relatively large pads on the chip periphery and routing the interconnects over the support areas 18 between the mirrors 24. It is preferred to maximize the area of the mirror surfaces while minimizing the overall size of the chip, that is, to have a large fill factor. A large number of wiring pads and horizontal interconnects in the top surface of the chip will severely decrease the fill factor.

Furthermore, the electrostatic actuators of the sort required for mirror arrays need drive voltages of at least 50V up to 200V or greater. On the other hand, typical digital integrated circuits used for control logic typically output signals of no more than 5V, and 2.3V or less is typical of modem integrated circuits. Thus, the high-voltage and low-voltage circuits process and output signals differing by at least a factor of ten. High-voltage integrated circuits can be fabricated, but they tend to be significantly larger than low-voltage control ICs of the same complexity, and it is difficult to integrate high-voltage and low-voltage circuitry on a same chip. In another approach, some proposals have been made to include the electronics in the silicon substrates being used to fabricate the MEMS mirrors. However, the processing to fabricate semiconductor integrated circuits, whether for high or low voltage, differs significantly from the processing to fabricate MEMS structures and melding the two would at a minimum unduly complicate the joint fabrication process or introduce significant design compromises.

Some of the problems associated with electronic control of large MEMS arrays have been ameliorated by the pulse width modulation control described by Garverick et al. (hereafter Garverick) in U.S. patent application, Ser. No. 09/884,676, filed Jun. 19, 2001, and published as International Publication WO 02/060045 A2, incorporated herein by reference in their entireties. This design separates the control circuitry into low-voltage and high-voltage sections. The high-voltage section may be limited to two high-voltage transistors and a level shifter for each actuator and driven by one low-voltage control signal while the low-voltage section is relatively complex. But low-voltage complexity is no particular problem since conventional integrated circuit fabrication techniques may be used if the high-voltage and low-voltage sections are fabricated on separate chips or application specific integrated circuits (ASICs). Nonetheless, each actuator requires its own high-voltage drive signal, and a like number of connections need to be made between the high-voltage and low-voltage sections if they are fabricated on separate chips.

Thus, while most of the required parts are available to form a MEMS-based optical cross connect, combining them and interconnecting them presents a challenge.

### SUMMARY OF THE INVENTION

An integrated micro electromechanical system (MEMS) in which a MEMS structure having an array of deformable mechanical elements and one or more integrated circuits (ICs) controlling the MEMS are bonded to a carrier having a wiring pattern formed therein for routing signals between the ICs and the MEMS.

The deformable elements may be mirrors formed as tiltable plates and supported by bendable torsion beams on the support structure. Such mirrors are usable as an optical switch.

Advantageously, a relatively thick handle layer may remain on the MEMS structure while it is being bonded to the carrier and only thereafter removed to release the mirrors and torsion bars or other deformable elements.

The MEMS elements may be electrostatically actuated. All the deformable elements or tiltable plates may form a single counter electrode. One or more electrodes may be formed on the carrier in correspondence to each of the deformable elements. The electrodes may be electrically connected through a wiring pattern in the carrier to control and drive circuitry.

The carrier may be formed of multiple levels of green tape, a form of green forms, each patterned with a horizontal and vertical wiring pattern. The stack of green forms are co-fired to form a ceramic multi-chip module.

The circuitry may include one or more electronic integrated circuits bonded to the carrier, either on the same side as or the side opposite from the MEMS structure. The integrated may include one or more separate high-voltage integrated circuits for driving the actuators and one or more low-voltage integrated circuits for controlling the drive circuits.

### BRIEF DESCRIPTION OF THE DRAWINGS

FIG. 1 is a functional and schematic cross-sectional view of a micro electromechanical system (MEMS) mirror formed in a substrate.

FIG. 2 is a plan view of a 2-dimensional array of MEMS mirrors.

FIG. 3 is a plan view of one MEMS mirror that is tiltable in two dimensions.

FIG. 4 is a cross-sectional view of an assembled optical switch based on tiltable MEMS mirrors including control electronics and drivers and integrated on a ceramic carrier.

FIG. 5 is a partially sectioned orthographic view of a ceramic multi-chip module (MCM) carrier usable with the invention.

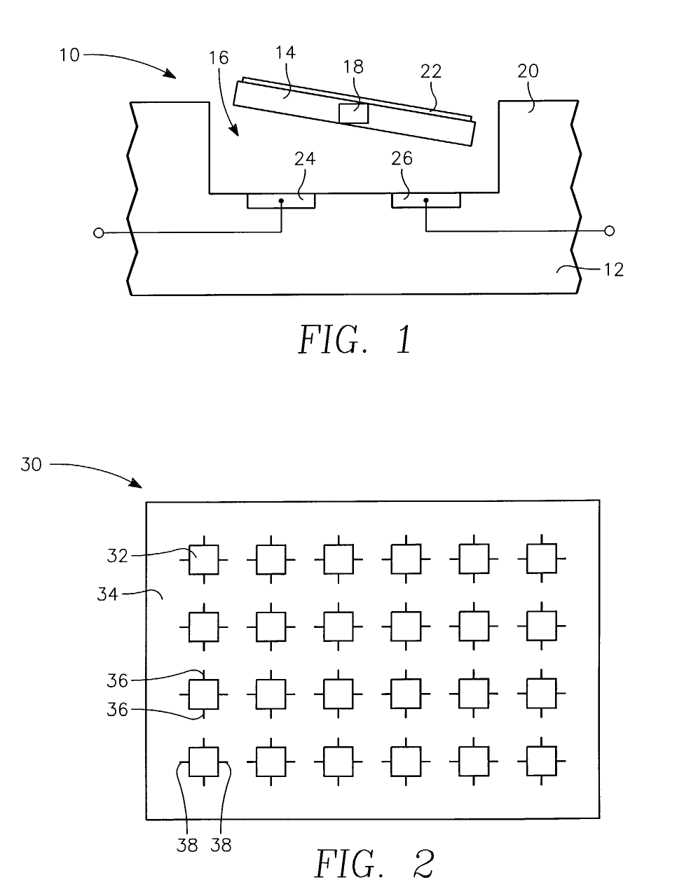

### DETAILED DESCRIPTION OF THE PREFERRED EMBODIMENTS

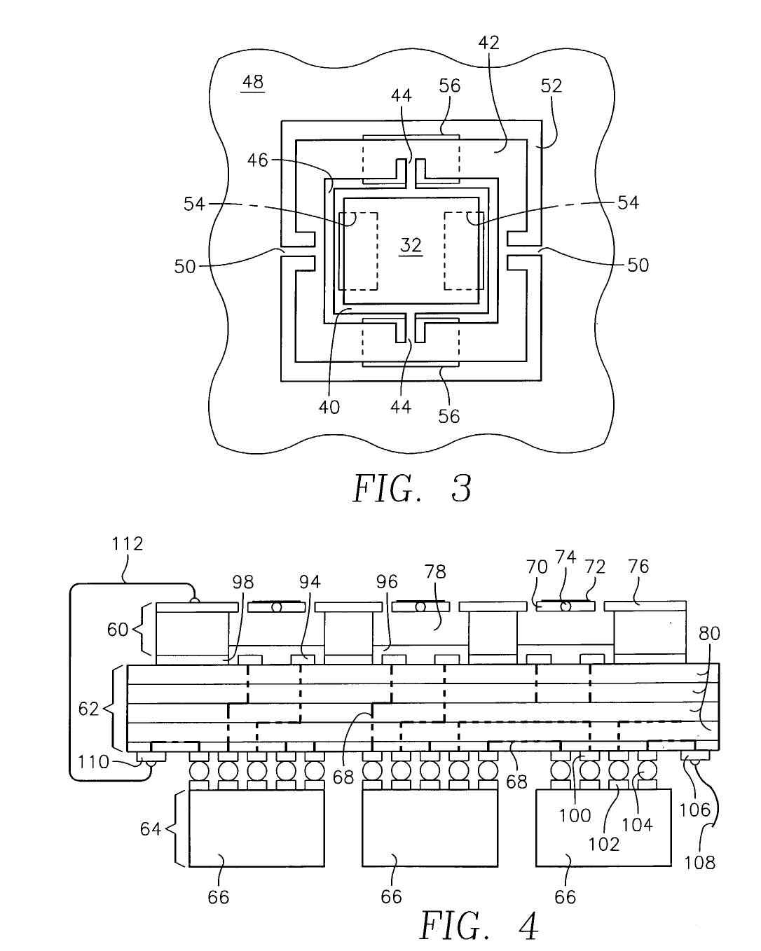

An embodiment of an optical switching device 30 based on a micro electromechanical system (MEMS), which is appropriate for the present invention, is illustrated schematically in plan view in FIG. 3. It includes an array of individually deformable mechanical elements, in particular, tiltable micro mirrors 32 formed in a substrate 34 and arranged in a 2-dimensional array. A gimbal structure allows each of a large number of mirrors 32 to tilt in one direction about an axis of a first pair of torsion beams 38 integrally joining the mirror 36 to the substrate 34 and to tilt in an perpendicular direction about an orthogonal axis of a second pair of similar torsion beams 38. The mirrors 32 are separately and independently tiltable by electrical actuators included within the MEMS device 30. Typically, opposed electrodes in the mirror 32 and substrate 34 allow independent electrostatic actuation about the respective axes for the respective mirrors 34.

The two-axis tilting may be accomplished by an electrostatically actuated gimbal structure, illustrated in plan view in FIG. 3, for controllably tilting each mirror 32 about two orthogonal axes. The mirror 32 is formed of a highly reflective metallic coating over a mirror plate 40 supported by a surrounding frame 42 through a first pair of opposed torsion beams 44 extending along a first axis. A horizontal gap 46 is formed between the mirror plate 40 and the frame 42 except for the torsion beams 44 extending across it. The frame 42 in turn is supported by a surrounding support structure 48 through a second pair of opposed torsion beams 50 extending along a second axis orthogonal to the first axis. Another horizontal gap 52 is formed between the frame 42 and the support structure 48 except for its torsion beams 50. The support structure 48 is part of the substrate 34 in which is formed an array of such mirrors. In this embodiment, the mirror plate 40, frame 42, and torsion beams 44, 50 are formed in a thin crystalline silicon layer also extending as the fixed support structure 48, but they are released from the underlying substrate in a microelectronic etching step.

One or more etching steps release the tiltable mirror plate 40 and form a cavity having a vertical gap formed in the substrate 34 underneath the mirror plate 40 and the frame 42. A first pair of electrodes 54 is formed in the substrate 34 and positioned on either side of the first axis beneath opposite sides of the mirror plate 40. A second pair of electrodes 56 is formed in the substrate 34 and positioned on either side of the second axis beneath opposite sides of the frame 42. The vertical gap separates the electrodes 54, 56 from the mirror plate 40 and the frame 42, which are held at a common potential and form a common counter electrode to the electrodes 54, 56 although the mirror plate 40 and the frame 42 are separately tiltable. The force between any electrode 54, 56 and the portion of the counter electrode it faces increases with the magnitude of the voltage between the electrode 54, 56 and the counter electrode. The pairing of the electrodes 54, 56 allows the net torque exerted on the tiltable elements 40, 42 to depend upon a difference of voltages applied to the electrode pair.

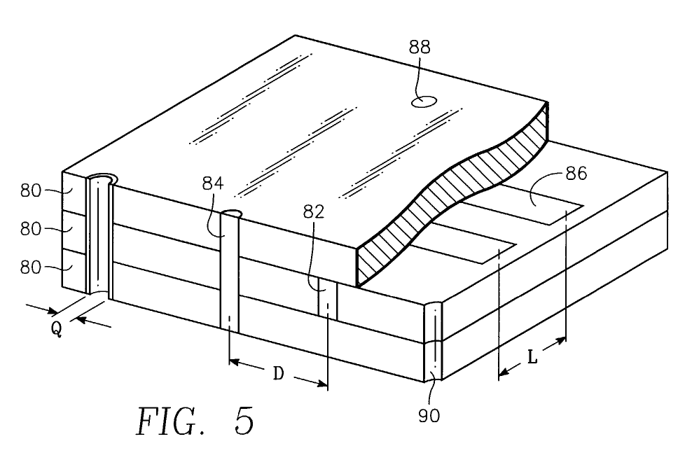

One embodiment of an integrated optical switch of the invention is illustrated in the schematic cross-sectional view of FIG. 4. It includes three levels of bonded structure. In summary, the three levels are the micro electromechanical system (MEMS) mirror level 60, a carrier level 62, for example, formed of a ceramic multi-layer substrate, and an electronic level 64, for example, composed of one or more electronic integrated circuits 66. The MEMS mirror level 60 contains the tiltable mirrors and is very fragile. With the exception of one required wiring connection, the MEMS mirror level need not be otherwise electrically connected despite the fact that hundreds to thousands of mirrors are being separately and individually controlled. The electronic level 64 contains one or more electronic integrated circuits, for example application specific integrated circuits 66, which use a relatively limited number of external system control signals to generate the mirror control and actuator drive signals for each of the large number of mirrors. The carrier level 62 not only mechanically supports both the MEMS mirror level 60 and the integrated circuits 66 of the electronics levels 64 but also interconnects the integrated circuits 66 among themselves, to the mirrors, and to the external control and power lines through metallized interconnects 68 formed in the carrier level 62. The carrier 62 is sometimes called an interposer because it is interposed between the MEMS structure and the electronics controlling the MEMS.

One embodiment of the MEMS mirror level 60 and its fabrication are described in more detail in the concurrently filed related application referenced above. That process and resultant structure of the invention of the related application are separable from the present invention but may be used therewith. The description of the related application will be briefly summarized now. For simplicity, FIG. 4 illustrates a mirror tiltable in only a single-axis direction. The extension to the two-axis tiltable mirror of FIGS. 2 and 3 is straightforward. The described embodiment includes an array of tiltable mirror plates 70 with highly reflective mirrors 72 coated on them. The mirrors plates 70, their torsion beams 74, and a surrounding support portion 76 are photolithographically defined from a silicon device layer of a first, mirror silicon-on-insulator (SOI) wafer. An SOI wafer includes a thin oxide layer formed intermediate a thick silicon handle layer, typically a silicon wafer, and a relatively thin silicon device layer, preferably single-crystal silicon. Cavities 78 intended to underlie corresponding mirror plates 72 are etched from a thicker silicon device layer of a second SOI, cavity wafer. The two SOI wafers are bonded together, and diced into MEMS chips. Either before or after the bonding, the handle layer of the cavity SOI wafer is etched away. The description of the processing of the MEMS chip will be interrupted before the handle layer of the first SOI wafer is removed.

Although different implementations of the carrier level 62 enjoy many benefits of the invention, a ceramic multi-layer substrate offers several advantages. Ceramic substrate technology has been well developed in the electronics industry and is often implemented as a multi-chip module (MCM). Customized multi-layer ceramic substrates are commercially available according to designs submitted to the MCM manufacturer. Some such manufacturers are Kyocera, AmKor, Coorstek, and International Business Machine. A prototypical multi-layer ceramic substrate illustrated in the partially sectioned orthographic view of FIG. 5 includes several layers 80, each of which is originally formed of a tape of a ceramic powder and sintering aid or solvent in green form well known in sintering. The tape may have a thickness of, for example, of between 250 and 375 μm, and can be formed of a ceramic powder for either high-temperature or low-temperature co-firing, such as alumina, aluminum nitride, or quartzite.

The green form tape can be easily patterned with via holes and other structural effects. The via holes are metallized to form an electrical via. The vias can be a via 82 extending through only one layer 80 or, by proper alignment with other such vias in adjacent layers 80, a via 84 extending through several layers 80. The via diameter Q may be as small 75 μm and the via spacing D may be as small as 100 μm, both consistent with the dimensions of the MEMS mirror array. Also horizontal interconnects 86 connecting two vias 84 on the same or different layers 80 may be formed on at least one surface of each layer 80 with widths and spacings L as small as 100 μm, and contact pads 88 may be formed on the outer surfaces of the top and bottom layers 80 to connect an external electrical line to an underlying via in the ceramic carrier. The metallizations may be formed of a metal ceramic mix that survives the sintering or firing as an electrical conductor. The metal ceramic mix may be deposited by either standard silicon integrated circuit techniques such as sputter depositing alternate layers of metal and oxide or plasma-enhanced chemical vapor deposition. Screen printing or other techniques are also available. Corner castellations 90 (not accurately illustrated with respect to the sectioned vias 82, 84) facilitate alignment between the different layers 80 and orientation of the assembled structure. The fired ceramic substrate 62 is stiff enough that it may be fixed with screws or other fastening means to a package containing the free-space optics described by Golub.

The different layers 80 are formed with independently determined metallization structures, thus allowing a complex interconnect structure. The different layers 80 while in green form are stacked together with the metallization structure properly aligned between the layers 80. The stacked structure is then co-fired in a common sintering process such that the green form tape is converted to a solid ceramic and the layers 80 are bonded together to form a ceramic MCM carrier with a complex internal interconnect structure and optional surface contact pads.

The MEMS side of the carrier 62 needs to be very smooth to satisfy the exacting optical requirements of the MEMS mirrors. Accordingly, at least one surface of the sintered carrier 62 is lapped and polished to the degree required for the application and optical design. Returning to FIG. 4, the capacitor electrodes 94 are deposited by patterned sputtering techniques on that polished surface to face the mirror plates 70 across the cavities 78 once the MEMS level 60 has been bonded to the MCM carrier 62. The electrodes 94 are aligned to the surface vias of the metallizations 68 in the MCM carrier 62 which will be driving them. The same type of plating may be used to form the contact pads on the bottom of the carrier 62. An isolating passivation layer 96, for example, of silicate glass, is deposited over the electrodes 74, which would otherwise be exposed to ambient and also be subject to shorting between the multiple electrodes 74 associated with a particular cavity 58.

The silicon device layer or its associated thin oxide layer of the cavity SOI wafer chip, that is, the chip defining the cavities 58, and its bonded mirror SOI wafer chip is aligned with and bonded to the MEMS carrier 62. At this stage, the handle layer of the cavity SOI wafer chip has been removed, but the mirror SOI wafer chip retains it handle layer, thus easing handling. Localized areas 98 of bonding agent are applied between the MEMS chip 60 and the MCM carrier 62. The bonding agent may be glass frit, other oxide, a thin film polymer, aluminum connection sintering, epoxy, divinyl siloxanebenzocyclobutene (BCB), epoxy, or other materials well known in flip chip bonding of integrated circuits on carriers. Depending upon the bonding agent, elevated temperature or pressure may be required. The handle layer of the mirror SOI wafer and the associated oxide layer are thereafter removed by an etching process, thereby releasing the mirror plates 70 and their torsion beams 74. The highly reflective mirror surfaces 72 are deposited, for example, by sputtering gold or silver using a shadow mask, which may be keyed to machined indicia in the ceramic MCM carrier. Also, any contact metallization to the conductive MEMS device layer may be performed. Heat treatment is performed on the metallization as required.

At this stage, the MEMS mirrors may be tested by standard wafer-probe techniques in which electrical contact is made to the via openings on the opposite (bottom) side of the MCM carrier 62 and voltage is applied to actuate the micro mirrors. The mid-assembly testing saves ASIC bonding and debonding if the MEMS structure proves defective, and rework of the MEMS structure is possible.

At this point, the fragile MEMS mirrors are exposed. To protect them during the subsequent ASIC bonding, the MEMS side of the may be covered with a removable cap that seals out dust and moisture.

The ASICs 66 are aligned with and front-side bonded to the side of the MCM carrier, preferably opposite the MEMS chip. The bonding process may include bonding pads 100, 102 deposited on the carrier 62 and ASICs 66 respectively and solder balls 104 used in solder bump bonding. The bonding pads 100, 102 may include the deposition of a stack of metals, called under-bump metallurgy (UBM), for example, a titanium/nickel/gold stack. The solder balls 104 deposited on one of the bonding pads 100, 102 may be composed of a 63/37 tin/lead solder. Other types of UBM materials and solder composition are well known in flip-chip bonding Concurrent with the deposition of the bonding pads 100 on the bottom MCM surface, external control bus interconnect pads 106 may be formed to provide a limited number of control signals and power to the ASICs 66 over control and power lines 108. A control connector may be permanently soldered to the interconnect pads 106 for receiving a ribbon cable from the external controller. Also, an internal drive pad 110 is used to bond a wire connection 112 to the conductive support portion 76 electrically connected to all the mirror plates 76 (and frames if included) acting as the counter electrode to thus supply the common node signal to all the counter electrodes. In practice, multiple wire connections 112 are connected to the commonly driven mirror plates 76 in order to minimize signal propagation delays. The actual solder-bump bonding may be performed by dipping the ASIC chips in flux and thereafter using automated pick-and-place equipment well developed for flip-chip bonding. The solder is typically reflowed at about 230° C. for 30 to 90 seconds.

If the ASICs 66 are separately fabricated from the carrier 62 supporting the MEMS chip 60, multiple ASICs can advantageously be used in the same module. The electronic circuitry required for a MEMS system involves both relatively complex but low-voltage control circuitry and relatively simple but high-voltage circuitry which directly drives the electrostatic actuators with voltages of typically greater than 50V. Fabricating such diverse circuitry in single silicon wafer is difficult and introduces design compromises. In contrast, the multiplicity of ASICs allows the low-voltage circuitry and high-voltage circuitry to be fabricated in separate chips with processes optimized for the respective circuit. Semiconductor processes are available for both high and low voltages, for example, using low-power CMOS circuitry. The ceramic substrate 62 interconnects the low-voltage and high-voltage ASICs 66. The multiplicity of ASICs also allow replication of ASICs across the module. For example, multiple and identical high-voltage drive ASICs may be positioned near the electrodes that they drive. Such a design both reduces the size of the high-voltage ASICs and shortens the high-power interconnects in the ceramic substrate. Another design, however, includes a single high-voltage ASIC that extends over substantially the same area as the mirror array in the MEMS level 60 and substantially straight vias extend from the high-voltage ASIC to the electrodes 94.

The MEMS mirror structure may be bonded to the ceramic substrate after the ASICs have been bonded to it. However, many types of MEMS bonding, such as the type using glass frit, tend to be a higher temperature processes, which may affect the ASIC flip-chip bonds. MEMS and ceramic substrates are relatively insensitive to temperatures used in ASIC bonding. It may be desirable to delay coating the mirror surfaces until after the ASIC bonding, particularly if gold or silver is used. However, that depends on the ASIC bonding temperature.

Although the ceramic MCM carrier is particularly advantageous, the invention can be extended to other types of carriers, including silicon, whether of single or multiple levels, and multi-level laminates such laminated printed circuit board or flex circuit. The double side bonding of the MEMS and the ASICs to the carrier is advantageous, but it is possible to bond both types of chips to the same side of the carrier.

Although the invention has been described with respect to a 2-dimensional array of mirrors tiltable about two axes, the invention is not so limited. One-dimensional array of mirrors and a single tilting axis may both be practiced according to the invention. The actuator electrodes need not be paired across the tilt axis, and other types of torsion beams may be used. Furthermore, the tilting plate need not include a mirror. The formation of one set of electrostatic electrodes on the carrier is particularly advantageous, but the invention is not so limited. Indeed, many aspects of the invention can be extended to other types of MEMS actuators, such as inductive current loops.

The invention thus uses readily available technology and processing to economically fabricate an integrated complex MEMS-based system. The system is robust enough to be fielded in a realistic network environment.

1. An integrated MEMS system, comprising:
a first substrate including an array of deformable mechanical elements formed in a first silicon layer thereof;
a second substrate bonded to and supporting said first substrate and including a wiring pattern formed therein electrically connected to actuators controlling deformations of said mechanical elements; and
at least one electronic integrated circuit bonded to and supported by said second substrate and being electrically connected to said wiring pattern.

2. The system of claim 1, wherein said second substrate comprises a plurality of levels bonded together, each level including a horizontal wiring arrangement and a plurality of electrical vias extending therethrough.

3. The system of claim 2, wherein said levels comprise layers of ceramic material cofired together to form a ceramic module

4. The system of claim 1, wherein said array of elements comprises a plurality of tiltable plates electrically connected together to form a common first electrode and separated from said second substrate by respective cavities and wherein a plurality of second electrodes are formed on said second substrate in opposition to said tiltable plates.

5. The system of claim 1, wherein said first substrate includes cavities formed under corresponding ones of said deformable mechanical elements.

6. The system of claim 1, wherein said at least one integrated circuit includes at least one first integrated circuit outputting electrical signals at a first electrical level and at least one second integrated circuit outputting electrical signals at a second electrical level at least ten times greater than said first electrical level.

7. The system of claim 6, wherein said at least one second integrated circuit drives electrostatic actuators associated with said mechanical elements.

8. The system of claim 1, wherein said at least one integrated circuit is bonded to said second substrate on an opposite side than said first substrate.

9. A MEMS optical switch, comprising:
an array N of tiltable mirrors formed in a silicon layer of a first substrate and having respective cavities below said mirrors;
a carrier having a wiring pattern formed therein; and
at least one electronic integrated circuit bonded to said carrier and having electrical connections connected to said wiring pattern.

10. The switch of claim 9, wherein said carrier includes electrodes formed on a surface thereof facing said cavities and electrically connected to said wiring pattern.

11. The switch of claim 9, wherein said carrier comprises a cofired ceramic multi-level substrate.

12. The switch of claim 9, wherein said at least one integrated circuit includes at least one first integrated circuit outputting electrical signals at a first electrical level and at least one second integrated circuit outputting electrical signals at a second electrical level at least ten times said first electrical level.

13. The switch of claim 9, wherein said at least one electronic integrated circuit is bonded to a side of said carrier opposite said first substrate.

14. The switch of claim 9, comprising electrostatic actuators associated with each of said mirrors across said cavities.

15. The switch of claim 14, wherein said at least one integrated circuit includes at least one first integrated circuit outputting electrical signals at a first electrical level and at least one second integrated circuit controlled by said at least one first integrated circuit and outputting electrical signals at a second electrical level at least ten times said first electrical level to drive said actuators.

16. A method of fabricating a MEMS array system, comprising the steps of:
forming in a first substrate an array of deformable mechanical elements bonded to a handle layer on a first side thereof and facing a corresponding array of cavities of a second side thereof;
a first step of bonding said second side of said first substrate to a second substrate having formed therein a wiring pattern comprising multiple levels of horizontal wiring and electrical vias connecting said multiple levels;
removing said handle layer after said bonding; and
a second step bonding at least one electronic integrated circuits to said second substrate and electrically contacting said at least one electronic integrated circuit to said wiring pattern in said second substrate.

17. The method of claim 16, wherein said at least one electronic integrated circuit comprises a first electronic integrated circuit outputting electrical signals at a first electrical level and a second electronic integrated circuit outputting electrical signals at a second electrical level at least ten times said first electrical level.

18. The method of claim 16, wherein said second substrate is a ceramic multi-level substrate.

19. The method of claim 16, wherein said second substrate is formed by the process of:
impressing respective horizontal and via wiring patterns in a plurality of green forms;
laminating said plurality of green forms into a stack; and
cofiring said plurality of green forms to form a ceramic module.

20. The method of claim 16, further comprising polishing a first side of said second substrate prior to said first bonding step.

21. The method of claim 19, further comprising plating electrodes on said first side of said second substrate after said polishing step.
